(19) United States
(12) Patent Application Publication
(10) Pub. No.: US 2026/0231789 A1
(43) Pub. Date: Aug. 6, 2026

(54) SEMICONDUCTOR DIE BONDING STRUCTURE AND METHODS OF FORMING THE SAME

(71) Applicant: Taiwan Semiconductor Manufacturing Company Limited, Hsinchu (TW)

(72) Inventors: Tzu Jung Tien, Hsinchu (TW); Jen-Yuan Chang, Hsinchu (TW)

(21) Appl. No.: 19/045,216

(22) Filed: Feb. 4, 2025

(51) Int. Cl. H01L 23/00; H01L 21/56; H01L 23/31; H01L 23/538; H01L 25/07; H01L 25/11

(52) U.S. Cl. CPC H10W 70/611; H10W 90/00; H10W 90/401; H10W 72/073; H10W 72/07338; H10W 72/07353; H10W 72/334; H10W 74/01; H10W 74/114; H10W 90/734; H10W 90/794

(57) ABSTRACT

An adhesive bonding structure and methods for forming the same. In some embodiments, a semiconductor device includes an interposer, and a plurality of dies attached to the interposer. In some embodiments, the plurality of dies includes at least one dummy die, and one semiconductor die. In some embodiments, the dummy die is attached to the top surface of the interposer by an adhesive layer. In some embodiments, the semiconductor device further includes a molding compound surrounding the plurality of dies.

### BACKGROUND

The semiconductor industry has continually grown due to continuous improvements in integration density of various electronic components, e.g., transistors, diodes, resistors, capacitors, etc. For the most part, these improvements in integration density have come from successive reductions in minimum feature size, which allows more components to be integrated into a given area (i.e., footprint).

In addition to smaller electronic components, improvements to the packaging of components seek to provide smaller packages that occupy less area than previous packages. Examples of the type of packages for semiconductors include quad flat pack (QFP), pin grid array (PGA), ball grid array (BGA), flip chips (FC), three-dimensional integrated circuits (3DICs), wafer level packages (WLPs), package on package (PoP), System on Chip (SoC) or System on Integrated Circuit (SoIC) devices. Some of these three-dimensional devices (e.g., 3DIC, SoC, SoIC) are prepared by placing chips over chips on a semiconductor wafer level. These three-dimensional devices provide improved integration density and other advantages, such as faster speeds and higher bandwidth, because of the decreased length of interconnects between the stacked chips.

In such three-dimensional devices, different elements may be bonded to one another to form a semiconductor package. The bonding may include dielectric-to-dielectric bonds as well as metal-to-metal bonds that allow for electrical connections via the metal-to-metal bonds between layers within the semiconductor structure. Fusion bonding, also known as direct bonding, involves a dielectric-to-dielectric bond allowing for connecting layers without electrical connections, such as between two flat, smooth dielectric layers. However, there are many challenges related to three-dimensional devices. For example, surface defects may prevent the bonding surfaces of different elements from properly bonding to one another. In addition, contaminates or particles may foul bonding surfaces and prevent proper bonding. In such instances a non-bond or defective bond may occur.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is an example vertical cross-sectional view of a semiconductor package with a bonded semiconductor die and an adhesive bonded dummy die according to various embodiments.

FIG. 1B is a top-down view of the region of the semiconductor package of FIG. 1A.

FIG. 2A is an example of an intermediate structure in a process of forming a semiconductor package with an interposer on a first substrate according to various embodiments.

FIG. 2B is a top-down view of the region of the intermediate structure of FIG. 2A.

FIG. 3A is an example of an intermediate structure of a semiconductor package in a process of attaching a semiconductor die and a dummy die to the interposer according to various embodiments.

FIG. 3B is a magnified vertical cross-sectional view of adhesive bonding the dummy die to the interposer of the intermediate structure with a bonding due to a contaminate defect of FIG. 3A.

FIG. 3C is a magnified vertical cross-sectional view of adhesive bonding the dummy die to the interposer of the intermediate structure with side gaps due to varying thicknesses of FIG. 3A.

FIG. 4A is a vertical cross-sectional view of an example of an intermediate structure of a semiconductor package in a process of attaching a dummy die with a patterned adhesive bonding structure according to various embodiments.

FIG. 4B is a top-down view of the region of the intermediate structure of FIG. 4A.

FIG. 5A is a vertical cross-sectional view of an example of an intermediate structure of a semiconductor package in a process of forming a molding compound surrounding the semiconductor die and the dummy die according to various embodiments.

FIG. 5B is a vertical cross-sectional view of an alternative intermediate structure of a semiconductor package in a process of forming a molding compound surrounding the semiconductor die and the dummy die according to various embodiments.

FIG. 5C is a vertical cross-sectional view of an alternative intermediate structure of a semiconductor package in a process of forming a molding compound surrounding the semiconductor die and the dummy die according to various embodiments.

FIG. 6A is a vertical cross-sectional view of an alternative intermediate structure of a semiconductor package in a process of planarizing the molding compound surrounding the semiconductor die and the dummy die according to various embodiments.

FIG. 6B is a top-down view of the region of the intermediate structure of FIG. 6A.

FIG. 7A is a vertical cross-sectional view of an intermediate structure of a semiconductor package in a process example of an intermediate structure with an alternative semiconductor die and dummy die configuration according to various embodiments.

FIG. 7B is a top-down view of the region of the intermediate structure of FIG. 7A.

FIG. 8A is a vertical cross-sectional view of an example of an intermediate structure of a semiconductor package with an alternative semiconductor die and dummy die configuration according to various embodiments.

FIG. 8B is a top-down view of the region of the intermediate structure of FIG. 8A.

FIG. 9 is a vertical cross-sectional view of an example of an intermediate structure of a semiconductor package in a process of detaching the first substrate according to various embodiments.

FIG. 10A is a vertical cross-sectional view of an example of an intermediate structure of a semiconductor package in a process of forming a second interposer on the interposer according to various embodiments.

FIG. 10B is a vertical cross-sectional view of an example of an intermediate structure of a semiconductor package in a process of forming bonding structures and solder material portions according to various embodiments.

FIG. 11A is a vertical cross-sectional view of an example of an intermediate structure of a semiconductor package in a process of forming an alternative second interposer on the interposer according to various embodiments.

FIG. 11B is a vertical cross-sectional view of an example of an intermediate structure of a semiconductor package in a process of forming bonding structures and solder material portions according to various embodiments.

FIG. 12A is a vertical cross-sectional view of an example of an intermediate structure of a semiconductor package in a process of attaching a second semiconductor die to the interposer according to various embodiments.

FIG. 12B is a vertical cross-sectional view of an example of an intermediate structure of a semiconductor package in a process of attaching a second semiconductor die to the interposer and forming a second portion of molding compound according to various embodiments.

FIG. 13 is a flowchart illustrating a method of forming a semiconductor package including an adhesive bonding structure according to some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. Various embodiments will be described in detail with reference to the accompanying drawings. Wherever possible, the same reference numbers will be used throughout the drawings to refer to the same or like parts. References made to particular examples and implementations are for illustrative purposes and are not intended to limit the scope of the claims.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments are disclosed herein that relate to an adhesive bonding structures within a semiconductor package device. Various embodiments disclosed herein address the challenge of non-bonding defects within the bonding interface due to surface abnormalities and/or contaminants. Various embodiments may reduce bonding defects thereby improving device yield. For example, in instances in which a particle or defect exists on a surface of a bonding layer, a gap may exist surrounding the particle in the fusion bond interface. As a result, a particle induced non-bond area may exist and the fusion bond may fail to adequately connect a first layer to a second layer, such as between a dummy die and a dielectric layer. Further, component warpage may cause a surface to have varying thickness or not be substantially flat. A gap may exist between the layers where the warpage occurred. As a result, a thickness induced non-bond area may exist and the fusion bond may fail to adequately connect the layers. Various embodiments include an adhesive bonding structure that may be flowable thereby creating an adequate bond between layers, even when particles exist on the surface or components have varying thickness due to warpage. As a result, various embodiments may fill in gaps caused by particle induced non-bonding and/or thickness induced non-bonding thereby improving bonding defects and improving device yield.

Related fusion bonding processes, also known as direct bonding, may be used to attach flat, smooth surfaces between non-circuit layers, such as two dielectric layers or a dielectric layer and a dummy die. Fusion bonding may involve bringing layers, such as two dielectric layers, into contact at room temperature, followed by a thermal annealing process to form chemical interactions between the two layers. As a result, fusion bonding may be highly sensitive to surface cleanliness and flatness. As such, in instances in which the surface has particles (e.g., contaminants) or surface irregularities, non-bonded areas may exist within the fusion bond. The non-bonded areas may result in defects that may cause the overall device to be discarded due to an improper bonding interface. Despite the advantages associated with fusion bonding, the process may be challenging due to the additional steps associated with surface preparation as well as the potential bonding failures caused by particles or surface roughness.

For example, particle-induced non-bonding and thickness-induced non-bonding are challenges in the fusion bonding process. Particle-induced non-bonding occurs when contaminants, such as dust or debris, exist on the bonding surfaces. The particles may create gaps between the bonding surfaces. These gaps may prevent complete adhesion, which may result in non-bonded areas. The non-bonded areas may lead to device defects that compromise the integrity and performance of the semiconductor package device.

As another example, thickness-induced non-bonding arises from variations in the thickness of the bonding layers caused by warpage or manufacturing defects. In the instance in which the bonding surfaces are not uniformly flat, certain areas may fail to come into complete contact with the opposing surface during the fusion bonding process. Such incomplete contact may lead to non-bonded regions. The non-bonded regions may cause issues such as mechanical weaknesses, ultimately affecting the reliability and functionality of the semiconductor device. The non-bonded regions may ultimately result in the semiconductor device being discarded, thereby decreasing overall yield.

To address non-bonding in fusion bonds, either by particle-induced non-bonding and/or thickness-induced non-bonding, several strategies are commonly used. For example, surface treatments and coatings may enhance adhesion properties, such as electroplating a thin layer of material to improve surface adhesion. Additionally, compatible materials may be selected to mitigate non-bonding issues, such as silicon and silicon dioxide which have similar thermal expansion coefficients that may maintain a strong bond during temperature fluctuations. Optimizing bonding conditions, such as adjusting temperature, pressure, and bonding time, may further improve bond quality. Ensuring clean and contaminant-free surfaces through proper cleaning and preparation, such as polishing techniques, may provide surfaces with adequate bonding and geometric properties. Introducing intermediate layers that bond well with both primary materials, such as silicon-based materials, may act as a bridge, further enhancing adhesion. Additionally, designing bonding surfaces with mechanical interlocking features, such as micro-textures, nano-scale structures, and lattice structures, may strengthen the bond thereby mitigating the effects of the non-bonding areas. While these strategies are often used individually or in combination to address specific challenges in fusion bonding processes, non-bonded regions may still cause defects within the bonding interface of the fusion bond thereby reduce performance, reliability, and yield.

Various embodiments are disclosed herein that provide an adhesive bonding structure configured to create a proper and adequate bonding interface that is substantially free from non-bonded regions caused by both particles induced non-bonding and thickness induced non-bonding. As a result, various embodiments disclosed herein may enhance thermal conductivity, reduce costs, and reduce bonding defects thereby resulting in improved yield and functionality of semiconductor devices. Various embodiments disclosed herein may be applicable to semiconductor devices with a stacking structure, advanced packaging, chip stacking, silicon photonics, or 3D fabrics.

In some embodiments, a semiconductor package device includes an interposer, and a die bonded to the interposer using an adhesive material. The adhesive material may substantially fill in any gaps located between the die and the interposer caused by either particle induced non-bonding or thickness induced non-bonding. The semiconductor package device may also include a molding compound surrounding the die to create a smooth top surface, protect and encapsulate the dies, and maintain electrical insulation properties. The adhesive may be patterned, for example in a line pattern, lattice pattern, or honeycomb pattern, thereby increasing the surface area between the interposer and die and preventing delamination between the interposer and the die attached via the adhesive material.

In a further embodiment, the semiconductor package device includes an interposer, a semiconductor die that may be bonded to the top surface of an interposer as well as a dummy die bonded to the top surface of the interposer using an adhesive material. The semiconductor die may be attached to the top surface of the interposer by a metal-to-metal and/or dielectric-to-dielectric bond, and the dummy die may be attached to the top surface of the interposer by an adhesive layer. The adhesive layer may substantially fill in any gaps located between the dummy die and the top surface of the interposer caused by particle induced non-bonding or thickness induced non-bonding. The semiconductor package device may further include a molding compound surrounding the semiconductor die and the dummy die that provides structural support and protects the dies from environmental factors, such as moisture, heat, and chemicals. The molding compound may create a substantially flat surface above the semiconductor die and dummy die, even in instances where the semiconductor die and the dummy die have varying heights. Further, a carrier wafer may be attached above the molding compound by a second adhesive layer which may improve heat dissipation efficiency in the semiconductor device. Similarly to the adhesive layer between the dummy die and the interposer, the second adhesive layer may substantially fill in any gaps caused by particle induced non-bonding and/or thickness induced non-bonding creating an adequate bonding interface. Based on semiconductor device packaging and needs, additional semiconductor dies and/or dummy dies may be attached to the top surface of the interposer by dielectric-to-dielectric and/or metal-to-metal bonding and adhesive bonding structures, respectively. Further, an additional semiconductor die may be attached to a bottom surface of the interposer and an additional molding compound may surround the additional semiconductor compound to create a buffer thereby reducing die cracking in small chip designs. An additional substrate may also be attached to the bottom surface of the interposer, such as a silicon substrate or a dielectric substrate, with vias located through the substrate in larger chip designs.

In yet a further embodiment, a method for forming a semiconductor package device includes forming an interposer and applying an adhesive layer on the top surface of the interposer to attach a die to the interposer via the adhesive layer. Additionally, the method may include flowing an additional amount of adhesive to fill in any gaps between the interposer and the die caused by particle induced non-bonding or thickness induced non-bonding. The adhesive layer may be cured to a thickness of between 0.1 μm to 10 mm to provide proper adhesion and stress balance. Further, the method may include attaching a semiconductor die to the interposer by a metal-to-metal and/or dielectric-to-dielectric bond. A molding compound may be formed to surround the die and semiconductor die to provide structural support and protect the dies from environmental effects. Further, the molding compound may provide a substantially flat surface to apply a second adhesive layer and attach a carrier wafer above the molding compound which may improve heat dissipation efficiency in the semiconductor device. The second adhesive layer may similarly fill gaps caused by particle induced non-bonding and/or thickness induced non-bonding between the molding layer and carrier wafer.

Various embodiments disclosed herein may provide multiple advantages and improvements. For example, various embodiments include an adhesive bonding structure that fills in gaps in the bonding interface caused by particle induced non-bonding or thickness induced non-bonding. For example, various embodiments may fill in large non-bonded areas caused by particles or automatically adjust for varying gap thickness due to component warpage. Additionally, various embodiments may decrease costs compared to traditional fusion bonding methods. Further, by improving the bonding interface between layers in the semiconductor device, various embodiments decrease bonding defects, increase semiconductor device yield, and decrease costs due to defective devices. Various embodiments may increase thermal conductivity and reduce die temperature based on the composition of the adhesive layer. The improved thermal conductivity may further improve overall semiconductor device performance by mitigating heat produced by dies and other device components. Further, embodiments may provide heat dissipation by including a carrier wafer, increase overall device area by including additional substrates, and reduce die cracking caused by smaller chip designs. In various embodiments, the bonding interface may be improved due to patterned adhesive layers which prevent delamination between layers. As a result, various embodiments may improve performance, efficiency, and yield of semiconductor devices due to improved bonding between various layers within the semiconductor device by the adhesive bonding structure.

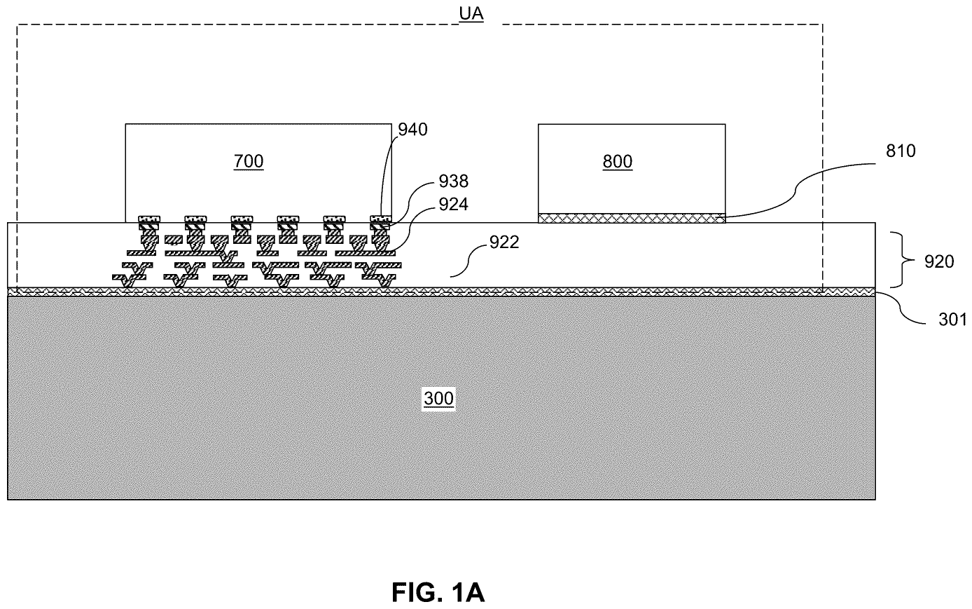

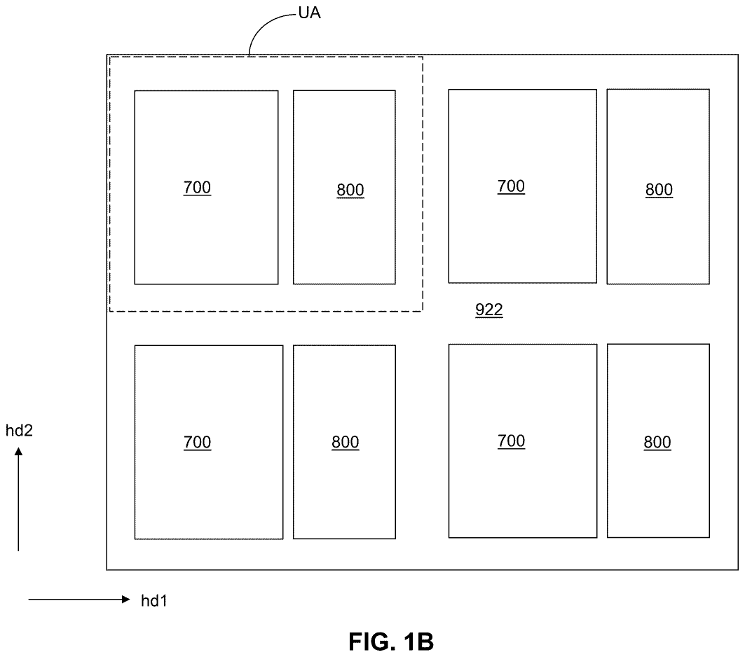

Referring to FIGS. 1A and 1B, a semiconductor package device may include a semiconductor die 700 and a dummy die 800 attached to a top surface of an interposer 920 by a dielectric-to-dielectric and/or metal-to-metal bond and an adhesive material 810, respectively. The semiconductor die 700 may be a functional die such as an high band-width memory (HBM), system on a chip (SoC), voltage regulator modulator (VRM), connector, or other appropriate dies that include circuits that are electrically connected to the interposer 920 by die bonding pads 940 and interposer bonding pads 938. The interposer bonding pads 938 may further be electrically connected to interconnect wirings 924 formed in a dielectric layer 922. Thus, the semiconductor die 700 may be bonded to the interposer 920 using a dielectric-to-dielectric and/or metal-to-metal bond that bonds both metal contacts between the semiconductor die 700 and interposer 920 as well as a direct fusion bond (i.e., dielectric-to-dielectric bond) between the semiconductor die 700 and interposer 920.

The dummy die 800 may be a die without circuits that provides structural support, dicing boundaries, or other purposes. The dummy die 800 may be attached to the interposer 920 by the adhesive material 810 instead of a fusion bond. The adhesive material 810 may substantially fill in any gaps between the dummy die 800 and the interposer 920 caused by either particle induced non-bonding or thickness induced non-bonding. The adhesive material 810 may thereby provide a proper bonding interface between the dummy die 800 and the top surface of the interposer 920 substantially free of non-bonded areas and bonding defects. Further, the interposer 920 may be attached to a substrate 300 by an additional adhesive layer 301. Similar to the adhesive material 810, the adhesive layer 301 may provide a proper bonding interface substantially free from gaps or defects.

The semiconductor die 700 and the dummy die 800 may be located within a unit area UA of the semiconductor device, which is the area of a repetition unit that may be repeated in a two-dimensional array over the substrate 300. As shown in FIG. 1B, the semiconductor device may include multiple repeating unit areas UA with semiconductor dies 700 and dummy dies 800 attached to the interposer 920 above the dielectric layer 922 of the interposer 920.

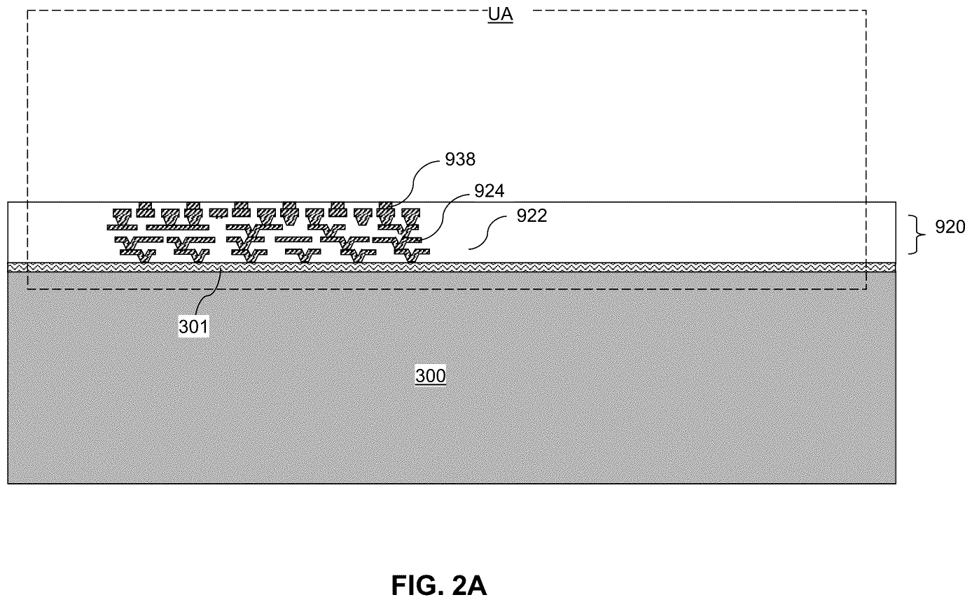

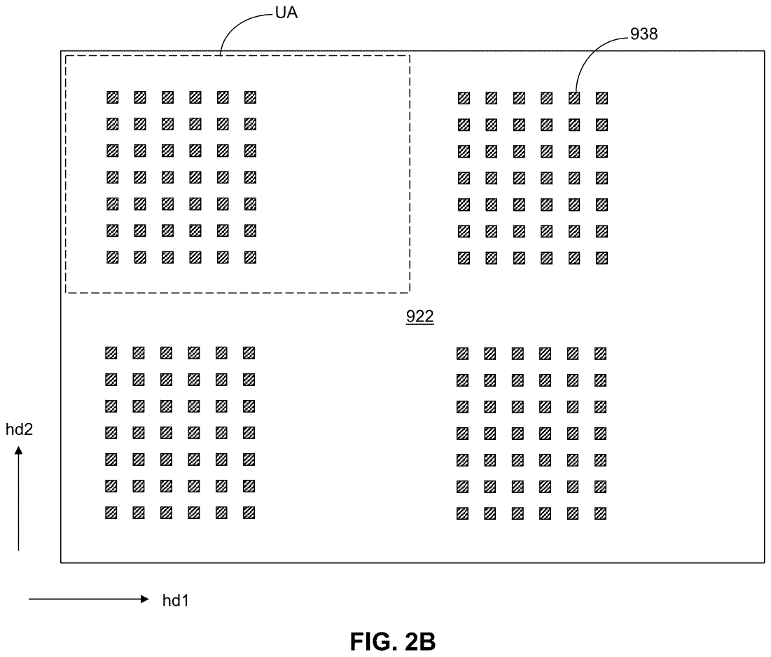

Referring to FIGS. 2A and 2B, an intermediate structure of semiconductor package device according to some embodiments may include a substrate 300 and an interposer 920 formed on a front side surface of the substrate 300. The substrate 300 may include an optically transparent substrate, such as a glass substrate or a sapphire substrate. The diameter of the substrate 300 may be in a range from 150 mm to 290 mm, although lesser and greater diameters may be used. In addition, the thickness of the substrate 300 may be in a range from 500 microns to 2,000 microns, although smaller and larger thicknesses may also be used. Alternatively, the substrate 300 may be provided in a rectangular panel format. The dimensions of the substrate in such alternative embodiments may be substantially the same.

A first adhesive layer 301 may be applied to the front-side surface of the substrate 300. The first adhesive layer 301 may provide an adhesive bonding structure that effectively fills in any gaps caused by particle induced non-bonding or thickness induced non-bonding. In some embodiments, the first adhesive layer 301 may be formed of a carbonaceous bonding material such as polyimide, molding compounds, or light resistance materials. The adhesive layer may further have a high thermal conductivity (e.g., greater than 1 W/m*K).

In some embodiments, the first adhesive layer 301 may be a light-to-heat conversion (LTHC) layer. The LTHC layer may be a solvent-based coating applied using a spin coating method. The LTHC layer may convert ultraviolet light to heat, which may cause the material of the LTHC layer to lose adhesion. Alternatively, the first adhesive layer 301 may include a thermally decomposing adhesive material. For example, the first adhesive layer 301 may include an acrylic pressure-sensitive adhesive that decomposes at an elevated temperature. The debonding temperature of the thermally decomposing adhesive material may be in a range from 150° C. to 200° C.

In some embodiments, an initial adhesive layer may be applied to the surface followed by additional adhesive layers to form the adhesive layer 301. The adhesive layer 301 may be flowable allowing for the adhesive layer 301 to fill in any gaps while being applied. In some instances, an initial layer may be applied and then any gaps caused by surface defects, particles, or warpages, may be filled with additional adhesive applied to the locations of the gaps.

The adhesive layer 301 may be cured by heating, UV irradiation, or other curing methods to increase hardness of the adhesive layer 301. The cured adhesive layer 301 may have a thickness of between about 0.05 μm to about 20 mm, about 0.1 μm to about 10 mm, about 1 μm to about 1 mm, about 5 μm to about 0.5 mm, or about 20 μm. The thickness of the cured adhesive layer 301 may balance adhesion and stress balance between the interposer 920 and the substrate 300.

The interposer 920 may be formed over the first adhesive layer 301 and may provide electrical connections between different layers of the semiconductor device. Specifically, the interposer 920 may be formed within each unit area UA, which is the area of a repetition unit that may be repeated in a two-dimensional array over the substrate 300. The interposer 920 may include dielectric layers 922 and wiring interconnects 924. The dielectric layers 922 include a respective dielectric polymer material such as polyimide (PI), benzocyclobutene (BCB), or polybenzobisoxazole (PBO). Other suitable materials may be within the contemplated scope of disclosure. Each dielectric layer 922 may be formed by spin coating and drying of the respective dielectric polymer material. The thickness of each dielectric layer 922 may be in a range from 2 microns to 40 microns, such as from 4 microns to 20 microns. Each dielectric layer 922 may be patterned, for example, by applying and patterning a respective photoresist layer thereabove, and by transferring the pattern in the photoresist layer into the dielectric layer 922 using an etch process such as an anisotropic etch process. The photoresist layer may be subsequently removed, for example, by ashing.

Each of the wiring interconnects 924 may be formed by depositing a metallic seed layer by sputtering, by applying and patterning a photoresist layer over the metallic seed layer to form a pattern of openings through the photoresist layer, by electroplating a metallic fill material (such as copper, nickel, or a stack of copper and nickel), by removing the photoresist layer (for example, by ashing), and by etching portions of the metallic seed layer located between the electroplated metallic fill material portions. The metallic seed layer may include, for example, a stack of a titanium barrier layer and a copper seed layer. The titanium barrier layer may have thickness in a range from 50 nm to 400 nm, and the copper seed layer may have a thickness in a range from 100 nm to 500 nm. The metallic fill material for the wiring interconnects 924 may include copper, nickel, or copper and nickel. Other suitable metallic fill materials are within the contemplated scope of disclosure. The thickness of the metallic fill material that is deposited for each wiring interconnect 924 may be in a range from 2 microns to 40 microns, such as from 4 microns to 10 microns, although lesser or greater thicknesses may also be used. The total number of levels of wiring in each interposer 920 (i.e., the levels of the wiring interconnects 924) may be in a range from 1 to 10. A periodic two-dimensional array (such as a rectangular array) of interposers 920 may be formed over the substrate 300. Each interposer 920 may be formed within a unit area UA.

In some embodiments, the interposer 920 includes interposer bonding pads 938 that may be formed of copper or a copper-containing alloy. Other suitable materials are within the contemplated scope of disclosure. The thickness of the interposer bonding pads 938 may be in a range from 5 microns to 60 microns, although lesser or greater thicknesses may also be used. The interposer bonding pads 938 may have horizontal cross-sectional shapes of rectangles, rounded rectangles, circles, regular polygons, irregular polygons, or any other two-dimensional curvilinear shape having a closed periphery. In some embodiments, interposer bonding pads 938 may be configured for microbump bonding (i.e., C2 bonding), and may have a thickness in a range from 10 microns to 30 microns, although lesser or greater thicknesses may also be used. In some embodiments, each array of interposer bonding pads 938 may be formed as an array of microbumps having a lateral dimension in a range from 10 microns to 25 microns and having a pitch in a range from 20 microns to 50 microns.

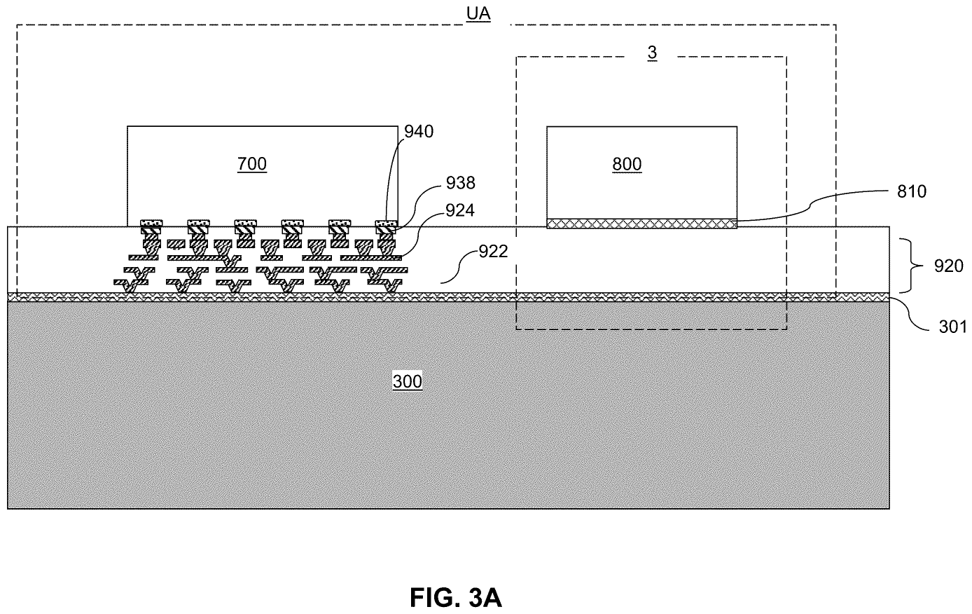

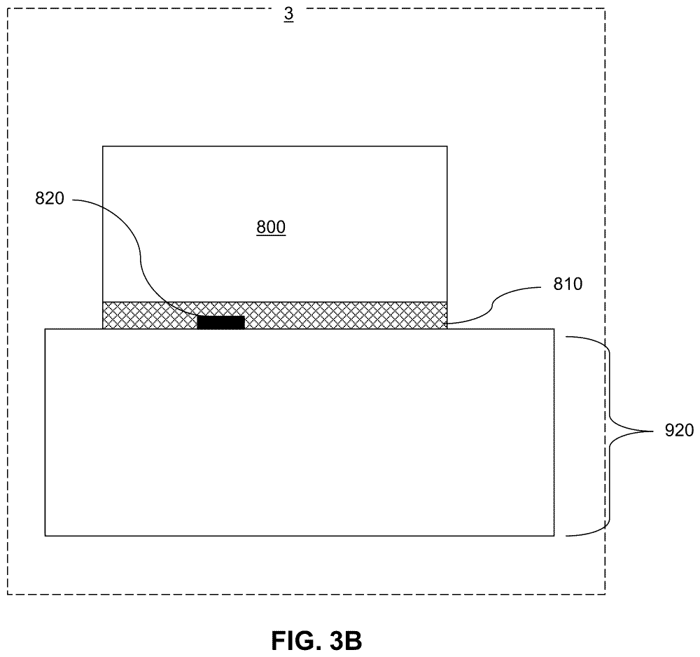

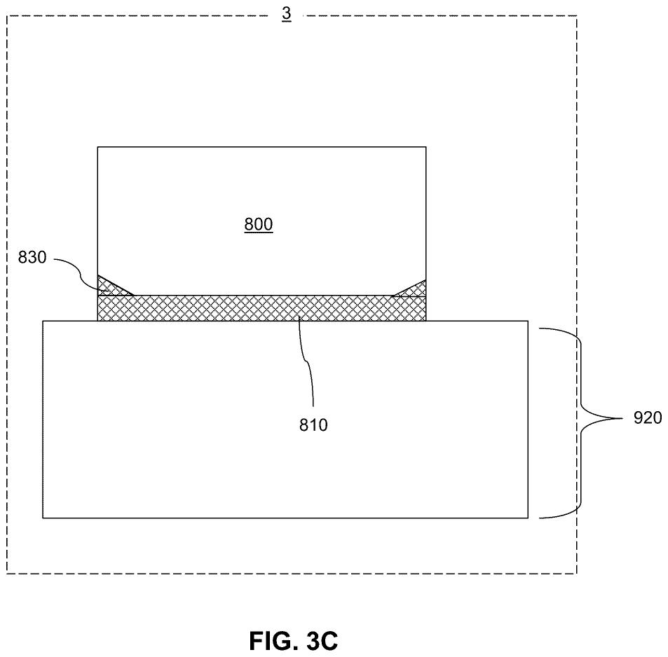

Referring to FIG. 3A, at least one semiconductor die 700 may be bonded to the interposer 920 through a dielectric-to-dielectric and/or metal-to-metal bond where the interposer bonding pads 938 are bonded to die bonding pads 940 of the semiconductor die 700 and the dielectric layer 922 is bonded to a dielectric portion of the semiconductor die 700.

In some embodiments, the semiconductor die 700 may be a high bandwidth memory (HBM) die that includes a vertical stack of static random access memory dies. In some embodiments, the at least one semiconductor die 700 may be a system on a chip (SoC) die. In other embodiments, the semiconductor die 700 may be a voltage regulator modulator (VRM). Other types of functional dies are contemplated within the scope of the disclosure.

The semiconductor die 700 may include a respective array of die bonding pads 940. The semiconductor die 700 may be positioned in a face-down position such that the die bonding pads 940 face corresponding interposer bonding pads 938. The semiconductor die 700 may be placed within a respective unit area UA. Placement of the semiconductor die 700 may be performed using a pick and place apparatus such that each of the die bonding pads 940 may be placed on a top surface of a respective one of the interposer bonding pads 938. During the pick and place process, contaminates, such as dust particles, may end up on the surface of the interposer 920. As more semiconductor dies 700 are added to the interposer surface using the pick and place apparatus, the probability of surface contamination of the interposer surface increases.

Additionally, a die 800 without circuits, also referred to as a dummy die 800, may be attached to the interposer 920 via an adhesive material 810. The dummy die 800 and semiconductor die 700 may be spaced apart by about 0.05 μm to about 400 mm, about 0.1 μm to about 300 mm, about 1 μm to about 200 mm, about 10 μm to about 50 mm, or about 50 μm. The spacing between the semiconductor die 700 and the dummy die 800 may be based on design structure (e.g., the type and size of each die). For example, the semiconductor die 700 and the dummy die 800 may be spaced to allow for gap fill material to be placed between the dies to avoid empty spaces.

The adhesive material 810 may be formed of polyimide, a molding compound, a light resistance material, an LTHC layer, or other appropriate adhesive materials. The adhesive material 810 may have a high thermal conductivity (e.g., greater than or equal to 1 W/m*K) to improve overall semiconductor device performance. The adhesive material may be formed of a carbonaceous material characterized by adhesion properties.

In some embodiments, the adhesive material 810 may be cured, or catalyzed, using UV irradiation, heating, or other curing methods. The cured adhesive material 810 may increase hardness thereby fixing the position of the die 800 on the interposer 920. In instances in which the adhesive material 810 may be easily accessible, heating curing methods may be appropriate. In contrast, in instances in which the adhesive material 810 is in an inaccessible area, UV irradiation curing methods may be appropriate. The cured adhesive 810 may have a thickness of about 0.05 μm to about 20 mm, about 0.1 μm to about 10 mm, 1 μm to about 5 mm, 10 μm to about 1 mm, or about 20 μm. The thickness of the cured adhesive layer 810 may balance adhesion with mechanical stress between the die 800 and the interposer 920 by the adhesive layer 810.

FIG. 3B shows a magnified view 3 of the dummy die 800 and adhesive material 810 shown in FIG. 3A. As shown, a particle 820, or a contaminate or defect, may be located on the surface of the interposer 920 that may cause particle induced non-bonding. The particle 820 may contaminate the surface of the interposer 920 during the pick and place process or other manufacturing processes. In some embodiments, an initial layer of adhesive material 810 may be placed on a portion of the interposer 920 associated with the die 800 placement. The adhesive material 810 may undergo a flowing process where any gap surrounding the particle 820 may be filled with the original initial layer of adhesive material 810 or by additionally added adhesive material 810. As shown, any gap surrounding the particle 820 is substantially surrounded by the adhesive material 810 thereby creating a proper bonding interface between the die 800 and the interposer 920.

FIG. 3C shows an alternative magnified view 3 of the dummy die 800 and adhesive material 810 shown in FIG. 3A. As shown, the dummy die 800 may undergo warpage during various fabrication processes that may cause a gap 830 that may cause thickness induced non-bonding. In some embodiments, an initial layer of adhesive material 810 may be placed on a portion of the interposer 920 associated with the die 800 placement. The adhesive material 810 may undergo a flowing process where the gap 830 may be filled with the original initial layer of adhesive material 810 or by additionally added adhesive material 810 directed towards the gap 830. As shown, any gap 830 is substantially filled by the adhesive material 810 thereby creating a proper bonding interface between the die 800 and the interposer 920.

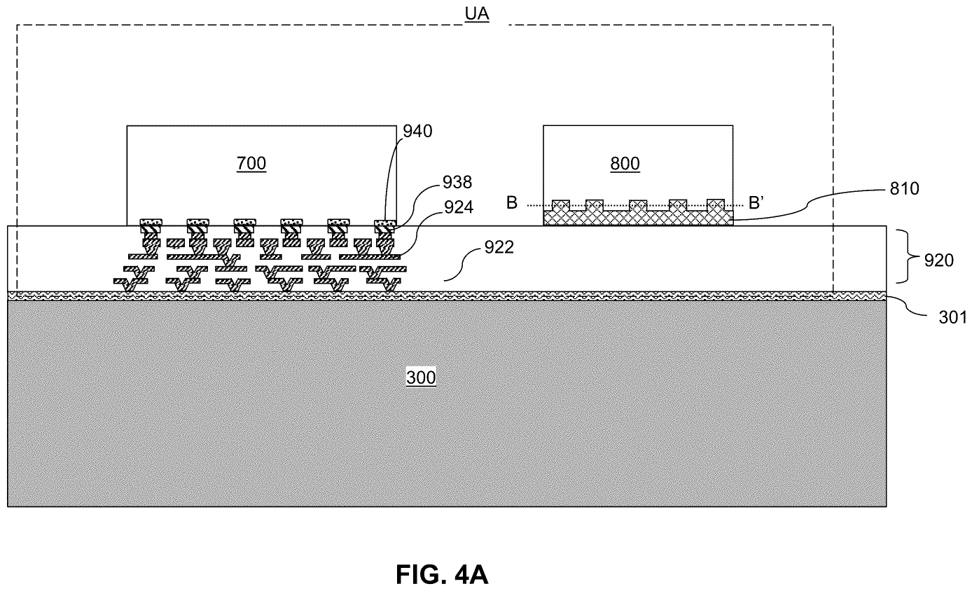

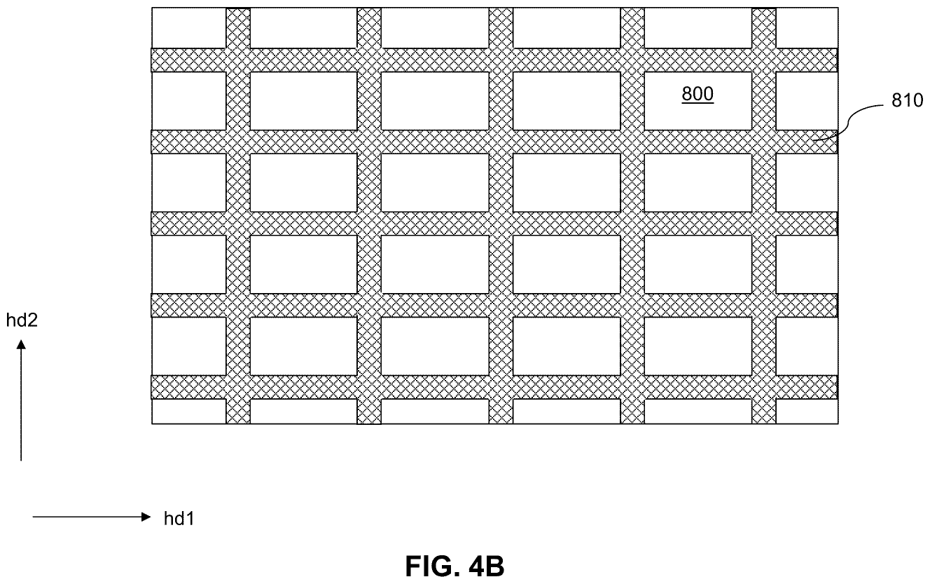

Referring to FIGS. 4A and 4B, the adhesive material 810 may be patterned. In some embodiments, the adhesive material 810 may be patterned as a line structure, honeycomb structure, lattice structure, spherical pattern, or other appropriate patterns. The patterned adhesive 810 may have a thickness of greater than 0.1 μm. For example, the thickness of the patterned adhesive 810 may be about 1 μm to about 20 μm, about 2 μm to about 15 μm, or about 5 μm to about 10 μm. The patterned adhesive material 810 may increase surface area of the adhesive thereby creating more contact area between the die 800 and the adhesive material 810. As a result of the increased surface area of the adhesive material 810, the adhesive material 810 may prevent delamination between the die 800 and the interposer 920.

The adhesive material 810 may be patterned by applying an initial base layer of adhesive material followed by only portions of adhesive material to form the patterned adhesive material 810. Alternatively, a single adhesive material layer may be applied and then portions of the adhesive material may be removed to create the patterned adhesive material 810. In some embodiments, only a portion of the adhesive material 810 may be patterned or multiple patterns may be used in different portions of the adhesive material 810 based on desired surface area between the adhesive material 810 and the die 800.

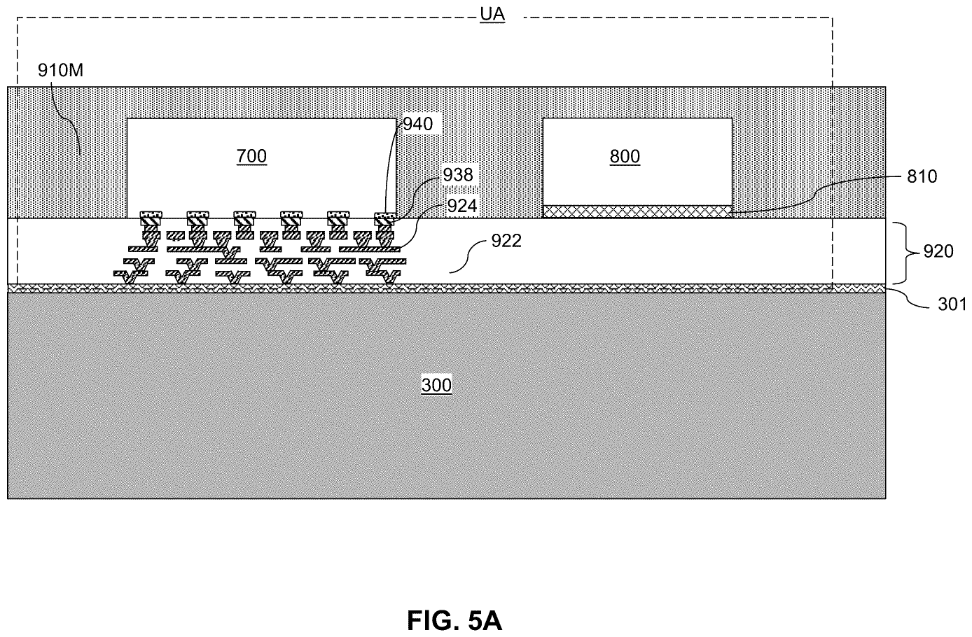

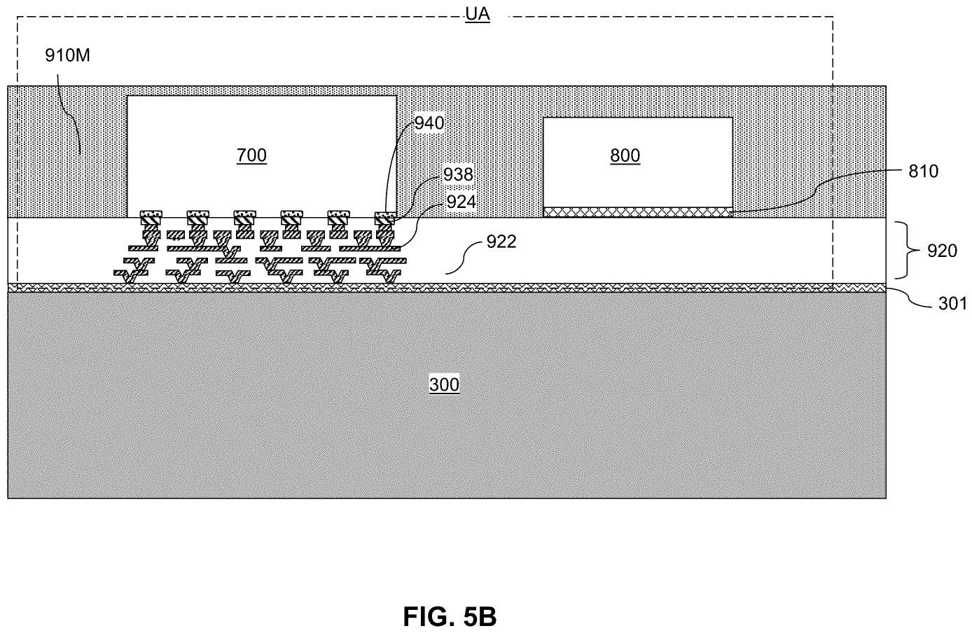

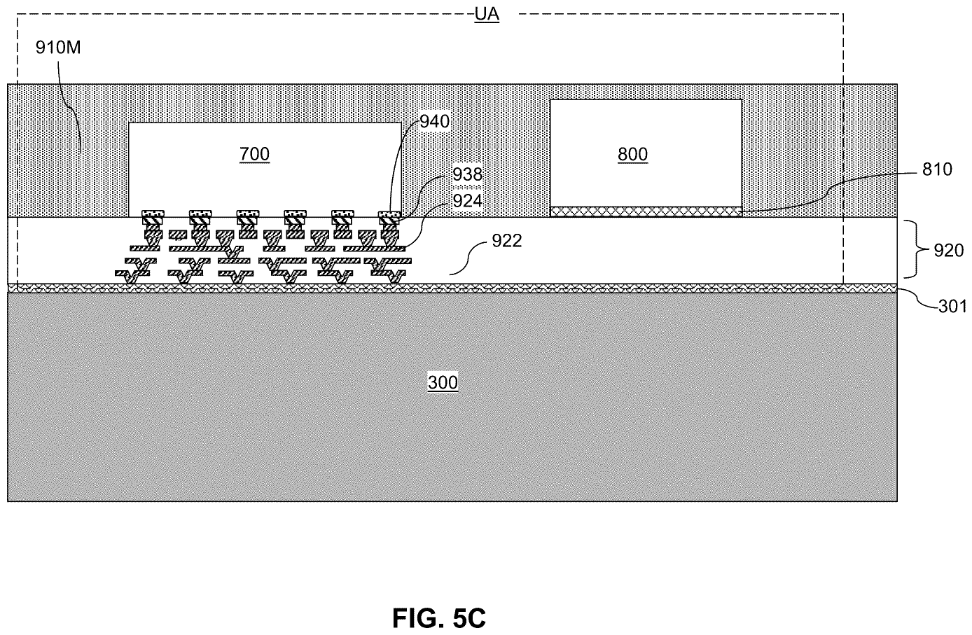

Referring to FIGS. 5A through 5C, a molding compound 910M may be formed in the gaps between contiguous assemblies of a semiconductor die 700 and a dummy die 800. The molding compound 910M may surround the semiconductor die 700 and the dummy die 800 to protect the semiconductor die 700 and the dummy die 800 from environmental factors such as contaminates, pressure, and moisture. Additionally, the molding compound 910M may provide structural support to the semiconductor device. The molding compound 910M may further provide stress balance between an edge and center of the adhesive material 810.

The molding compound 910M may be an epoxy molding compound (EMC) that includes an epoxy-containing compound that may be hardened (i.e., cured) to provide a dielectric material portion having sufficient stiffness and mechanical strength. The EMC may include epoxy resin, hardener, silica (as a filler material), and other additives. The EMC may be provided in a liquid form or in a solid form depending on the viscosity and flowability. Liquid EMC provides better handling, good flowability, less voids, better fill, and less flow marks. Solid EMC provides less cure shrinkage, better stand-off, and less die drift. A high filler content (such as 85% in weight) within an EMC may shorten the time in mold, lower the mold shrinkage, and reduce the mold warpage. Uniform filler size distribution in the EMC may reduce flow marks and may enhance flowability. The curing temperature of the EMC may be lower than the release (debonding) temperature of the first adhesive layer 301 in embodiments in which the adhesive layer includes a thermally debonding material. For example, the curing temperature of the EMC may be in a range from 125° C. to 150° C.

The EMC may be cured at a curing temperature to form an EMC matrix or a molding compound 910M that laterally surrounds and embeds the semiconductor die 700 and the dummy die 800. The molding compound 910M includes a plurality of epoxy molding compound (EMC) die frames that may be laterally adjoined to one another. Each EMC die frame is a portion of the molding compound 910M that is located within a respective unit area UA. Thus, each EMC die frame laterally surrounds and embeds the semiconductor die 700 and dummy die 800. Young's modulus of pure epoxy is about 3.35 GPa, and Young's modulus of the EMC may be higher than Young's modulus of pure epoxy by adding additives. Young's modulus of EMC may be greater than 3.5 GPa.

As shown in FIG. 5B, in some embodiments, the semiconductor die 700 may have a height greater than the dummy die 800. As shown in FIG. 5C, in other embodiments, the dummy die 800 may have a height greater than the semiconductor die 700. Regardless of the height of the semiconductor die 700 and the dummy die 800, the molding compound 910M may provide a substantially flat surface above the semiconductor die 700 and the dummy die 800 to which additional layers or components may be attached.

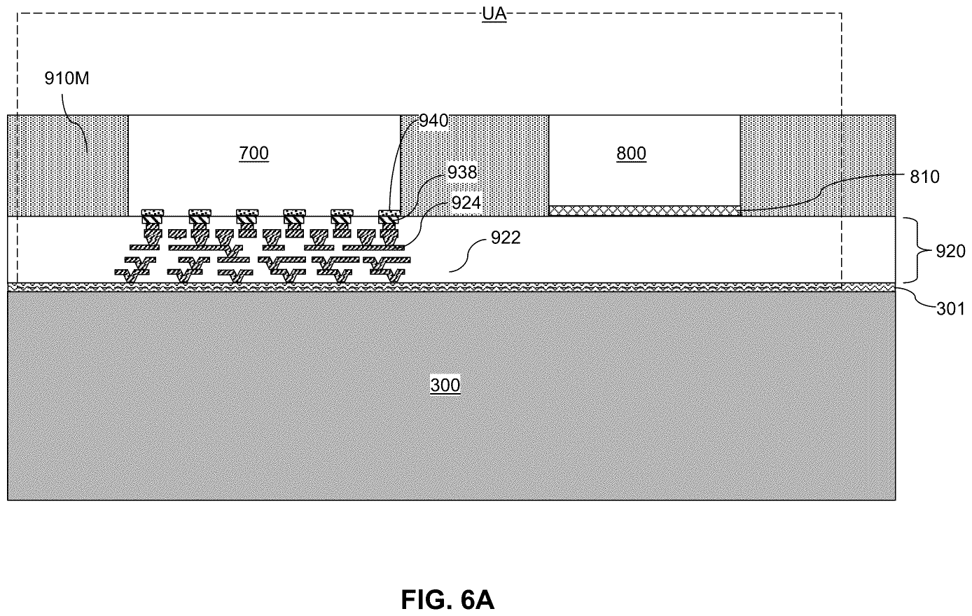

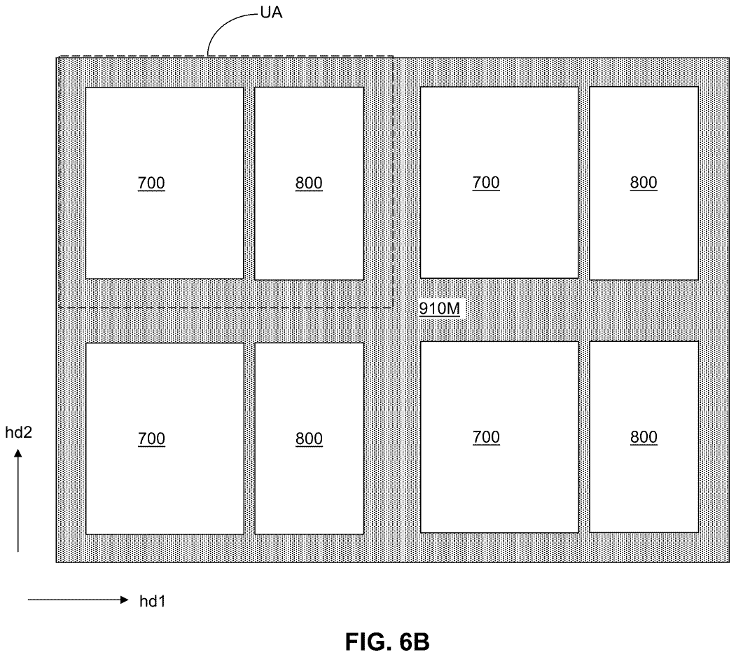

Referring to FIGS. 6A and 6B, the molding compound 910M may be smoothed (i.e., planaraized) to create a substantially smooth top surface. Portions of the molding compound 910M that overlies the horizontal plane and optionally including the top surfaces of the semiconductor die 700 and dummy die 800 may be removed by a planarization process. For example, the portions of the molding compound 910M that overlies the horizontal plane may be removed using a chemical mechanical planarization (CMP). Each portion of the molding compound 910M located within a unit area UA constitutes an EMC die frame.

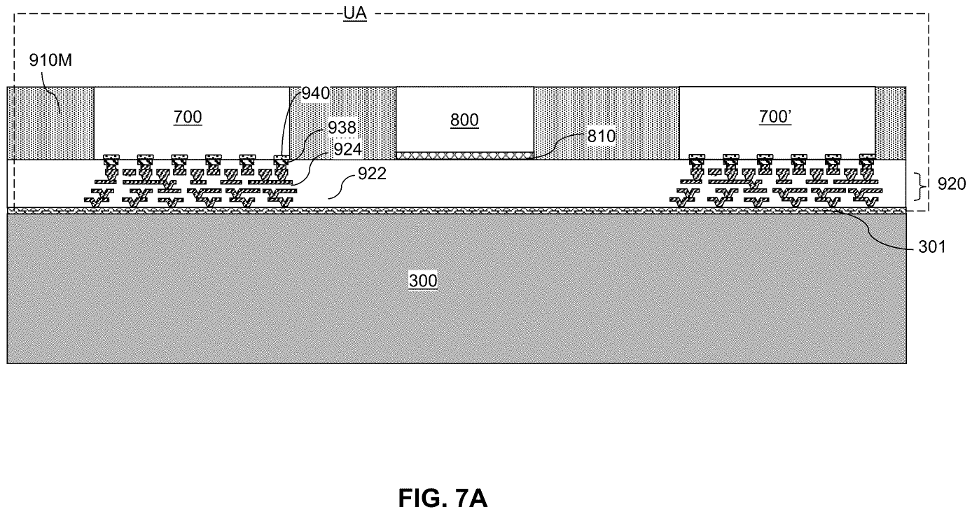

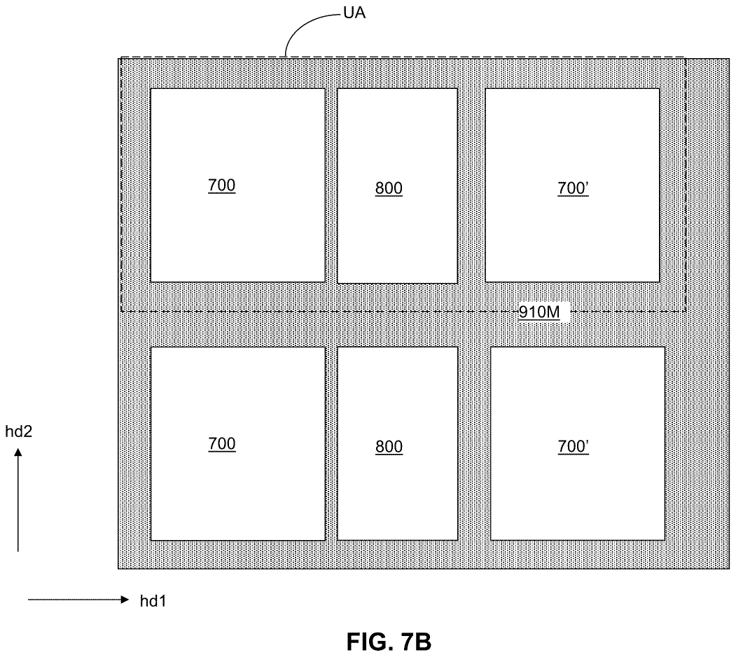

Referring to FIGS. 7A and 7B, an additional semiconductor die 700′, or an additional functional die 700′, may be attached to the interposer 920. The additional semiconductor die 700′ may be attached by a metal-to-metal and/or dielectric-to-dielectric bond in the same fashion as semiconductor die 700. The additional semiconductor die 700′ may be the same type of die as the semiconductor die 700 or a different type of semiconductor die. The dummy die 800 may be located between the semiconductor die 700 and the additional semiconductor die 700′. As shown, the unit area UA may include the semiconductor die 700, the dummy die 800, and the additional semiconductor die 700'. While three dies (e.g., two semiconductor dies and one dummy die) are shown, other combinations of dies with more dies is contemplated by the scope of the disclosure.

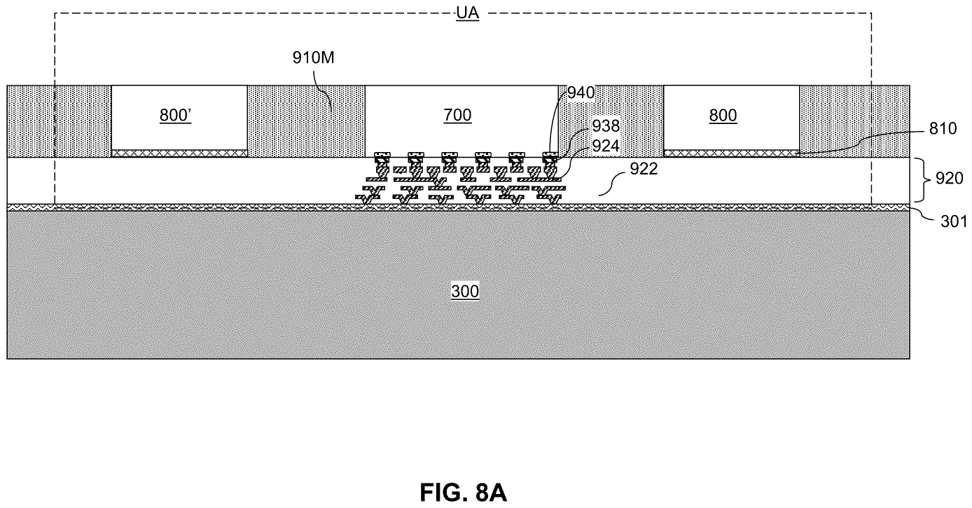

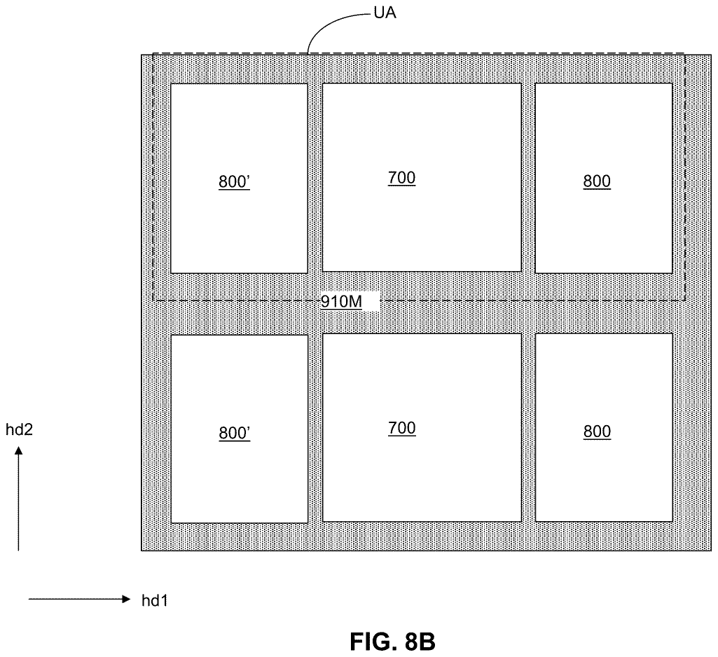

Similarly, referring to FIGS. 8A and 8B, an additional dummy die 800′ may be attached to the interposer 920. The additional dummy die 800′ may be attached by an adhesive layer 810. The semiconductor die 700 may be located between the dummy die 800 and the additional dummy die 800′. As shown, the unit area UA may include the dummy die 800, the semiconductor die 700, and the additional dummy die 800′. While three dies (e.g., a semiconductor die and two dummy dies) are shown, other combinations of dies with more dies is contemplated by the scope of the disclosure.

The molding material 910M may be adjusted in FIGS. 7A through 8B to adjust for stress applied to the different dies to prevent die warpage. The adhesive layer 810 may also be adjusted, for example the thickness, to prevent die warpage due to stress.

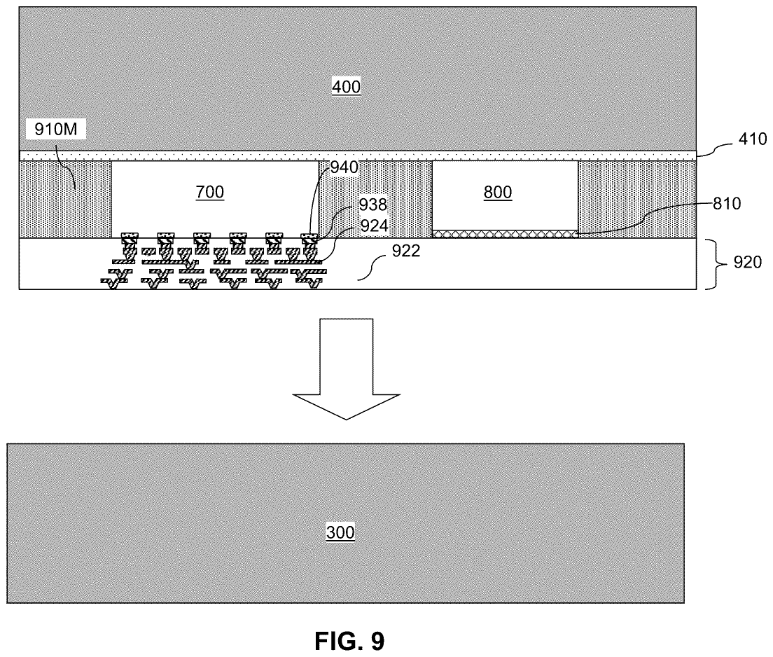

Referring to FIG. 9, a second adhesive layer 410 may be applied to the physically exposed planar surface of the molding compound 910M. In some embodiments, the second adhesive layer 410 may include the same material as, or may include a different material from, the material of the first adhesive layer 301. Alternatively, the second adhesive layer 410 may be formed of the same material as the adhesive material 810 and may substantially fill in any gaps between the molding compound 910M and the carrier wafer 400 caused by particle induced non-bonding or thickness induced non-bonding. The adhesion strength of the adhesion material 410 may be adjusted based on internal stress of stacking multiple layers.

The carrier wafer 400 may be attached via the adhesive layer 410 to improve heat dissipation efficiency. In some embodiments, the carrier wafer 400 may be a glass wafer formed of silicon dioxide, aluminum dioxide, or other materials. Alternatively the carrier wafer 400 may be formed of metal to provide a heat dissipation cover. The thickness of the carrier wafer 400 may be in a range from 500 microns to 2,000 microns, although lesser and greater thicknesses may also be used.

The first adhesive layer 301 may be decomposed by ultraviolet radiation or by a thermal anneal at a debonding temperature. In some embodiments in which the substrate 300 includes an optically transparent material and the first adhesive layer 301 includes an LTHC layer, the first adhesive layer 301 may be decomposed by irradiating ultraviolet light through the transparent carrier substrate. The LTHC layer may absorb the ultraviolet radiation and generate heat, which decomposes the material of the LTHC layer and causes the transparent substrate 300 to be detached from the reconstituted wafer. In some embodiments in which the first adhesive layer 301 includes a thermally decomposing adhesive material, a thermal anneal process at a debonding temperature may be performed to detach the substrate 300 from the interposer 920.

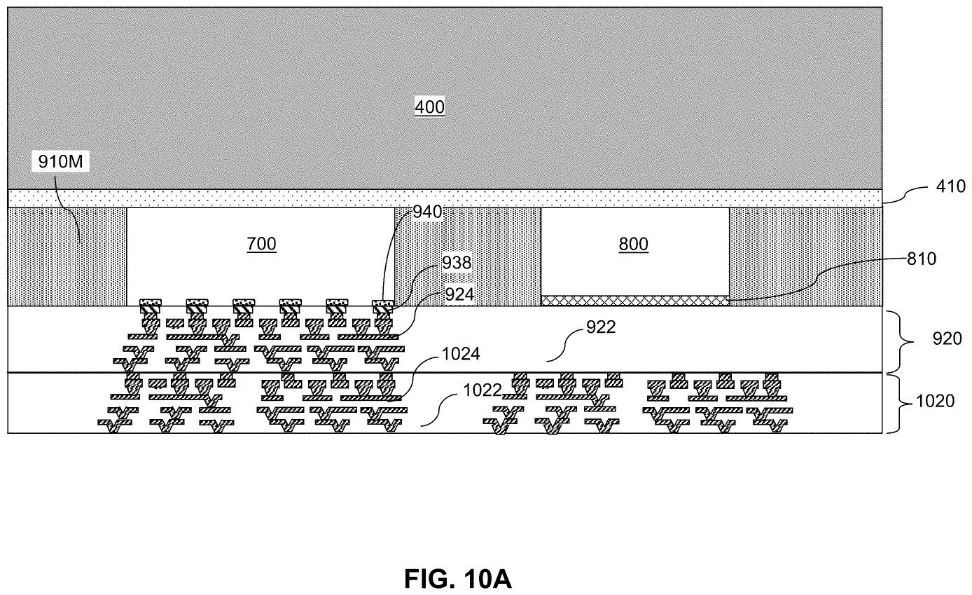

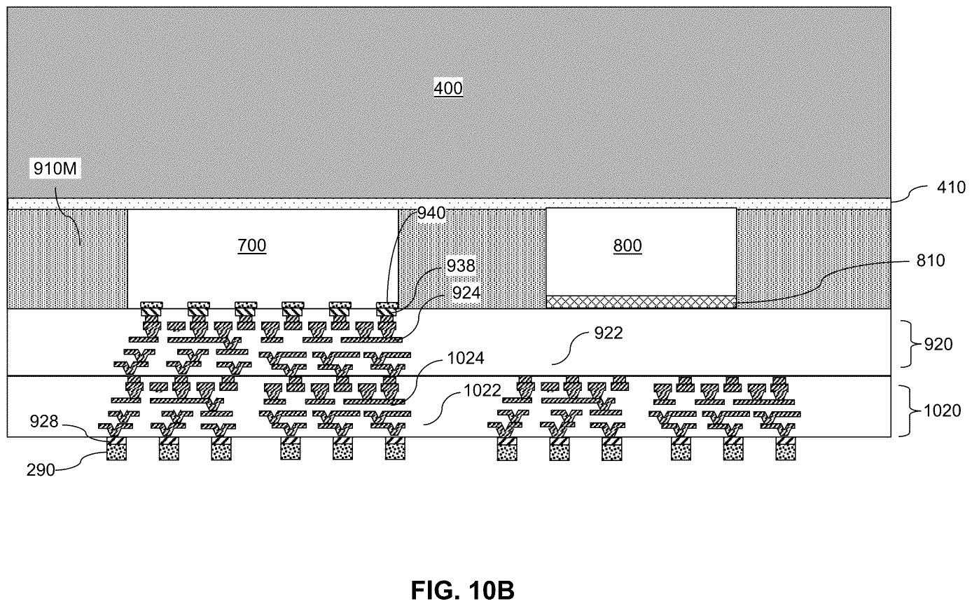

Referring to FIGS. 10A and 10B, an additional interposer 1020 may be formed on the interposer 920. The interposer 1020 may include dielectric layers 1022 with wiring interconnect structures 1024 formed in the dielectric layers 1022. The interposer 1020 may be formed in the same manner as interposer 920 described above.

Additionally, interposer bonding pads 928 and solder material portions 290 may be formed by depositing and patterning a stack of at least one metallic material that may function as metallic bumps and a solder material layer. The metallic fill material for the interposer bonding pads 928 may include copper. Other suitable materials are within the contemplated scope of disclosure. The thickness of the interposer bonding pads 928 may be in a range from 5 microns to 100 microns, although lesser or greater thicknesses may also be used. The interposer bonding pads 928 and the solder material portions 290 may have horizontal cross-sectional shapes of rectangles, rounded rectangles, or circles. Other suitable shapes are within the contemplated scope of the disclosure. In some embodiments in which the interposer bonding pads 928 are formed as C4 (controlled collapse chip connection) pads, the thickness of the interposer bonding pads 928 may be in a range from 5 microns to 50 microns, although lesser or greater thicknesses may also be used. In some embodiments, the interposer bonding pads 928 may be, or include, underbump metallization (UBM) structures. The configurations of the interposer bonding pads 928 are not limited to fan-out structures. Alternatively, the interposer bonding pads 928 may be configured for microbump bonding (i.e., C2 bonding), and may have a thickness in a range from 30 microns to 100 microns, although lesser or greater thicknesses may also be used. In some embodiments, the interposer bonding pads 928 may be formed as an array of microbumps (such as copper pillars) having a lateral dimension in a range from 10 microns to 25 microns and having a pitch in a range from 20 microns to 50 microns.

The interposer bonding pads 928 and the solder material portions 290 may be formed on the opposite side of the molding compound 910M relative to the interposer 920. The interposer bonding pads 928 may be located on an opposite side of the interposer bonding pads 938 relative to the dielectric layers 922 and may be electrically connected to a respective one of the interposer bonding pads 938.

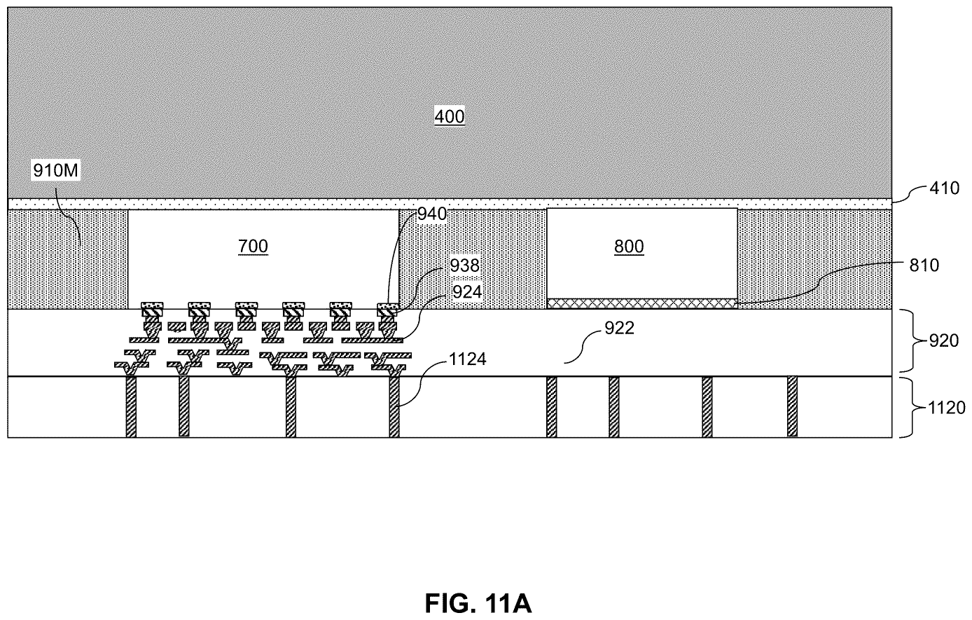

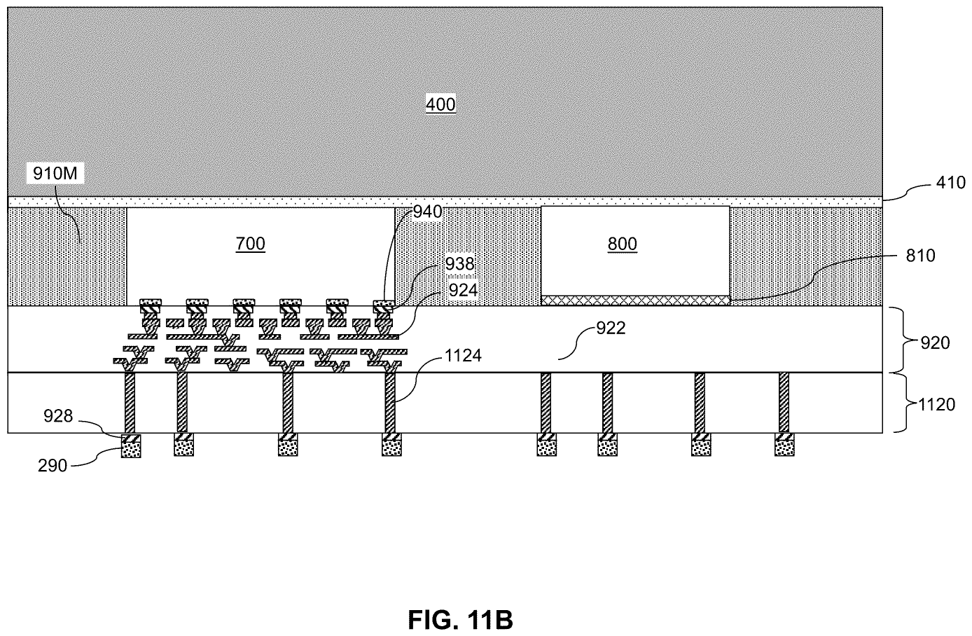

Referring to FIGS. 11A and 11B, alternatively, a substrate 1120 may be formed below the interposer 920. As shown, the circuit may extend beyond the interposer 920 through the substrate 1120 with vias 1124 located throughout to electrically connect additional components, elements, or layers. The substrate 1120 may be a silicon substrate, a dielectric substrate, or other appropriate substrates. Additionally, through vias 1124 may be formed in the substate 1120. In the instance where the substrate 1120 is a silicon substrate, the through vias 1124 may be through silicon vias (TSVs). In the instance where the substrate 1120 is a dielectric substrate, the through vias 1124 may be through dielectric vias (TDVs). Based on the material the substrate is formed of, the adhesive material 810 and/or 410 may be adjusted (e.g., thickened or thinned) based on mechanical stress caused by the additional substrate 1120.

Additionally, interposer bonding pads 928 and solder material portions 290 may be formed by depositing and patterning a stack of at least one metallic material that may function as metallic bumps and a solder material layer. The metallic fill material for the interposer bonding pads 928 may include copper. Other suitable materials are within the contemplated scope of disclosure. The thickness of the interposer bonding pads 928 may be in a range from 5 microns to 100 microns, although lesser or greater thicknesses may also be used. The interposer bonding pads 928 and the solder material portions 290 may have horizontal cross-sectional shapes of rectangles, rounded rectangles, or circles. Other suitable shapes are within the contemplated scope of the disclosure. In some embodiments in which the interposer bonding pads 928 are formed as C4 (controlled collapse chip connection) pads, the thickness of the interposer bonding pads 928 may be in a range from 5 microns to 50 microns, although lesser or greater thicknesses may also be used. In some embodiments, the interposer bonding pads 928 may be, or include, underbump metallization (UBM) structures. The configurations of the interposer bonding pads 928 are not limited to fan-out structures. Alternatively, the interposer bonding pads 928 may be configured for microbump bonding (i.e., C2 bonding), and may have a thickness in a range from 30 microns to 100 microns, although lesser or greater thicknesses may also be used. In some embodiments, the interposer bonding pads 928 may be formed as an array of microbumps (such as copper pillars) having a lateral dimension in a range from 10 microns to 25 microns and having a pitch in a range from 20 microns to 50 microns.

The interposer bonding pads 928 and the solder material portions 290 may be formed on the opposite side of the molding compound 910M relative to the interposer 920. The interposer bonding pads 928 may be located on an opposite side of the interposer bonding pads 938 relative to the dielectric layers 922 and may be electrically connected to a respective one of the interposer bonding pads 938.

The silicon-based substrate 1120 may be particularly advantageous in small semiconductor packages and may reduce die warpage. In contrast, the dielectric based substrate 1120 may allow for larger overall semiconductor devices (e.g., larger than a 300 mm silicon wafer).

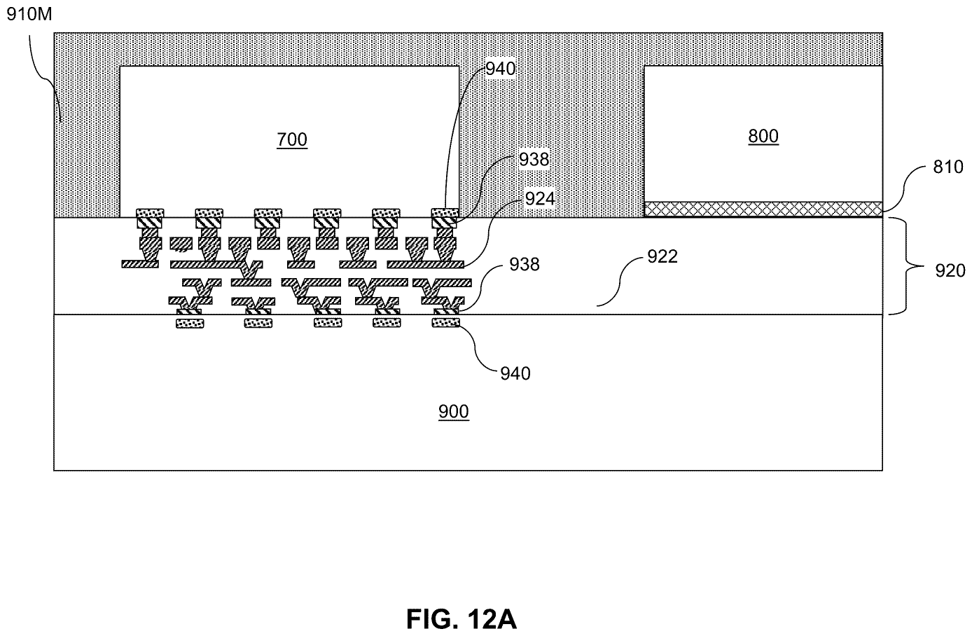

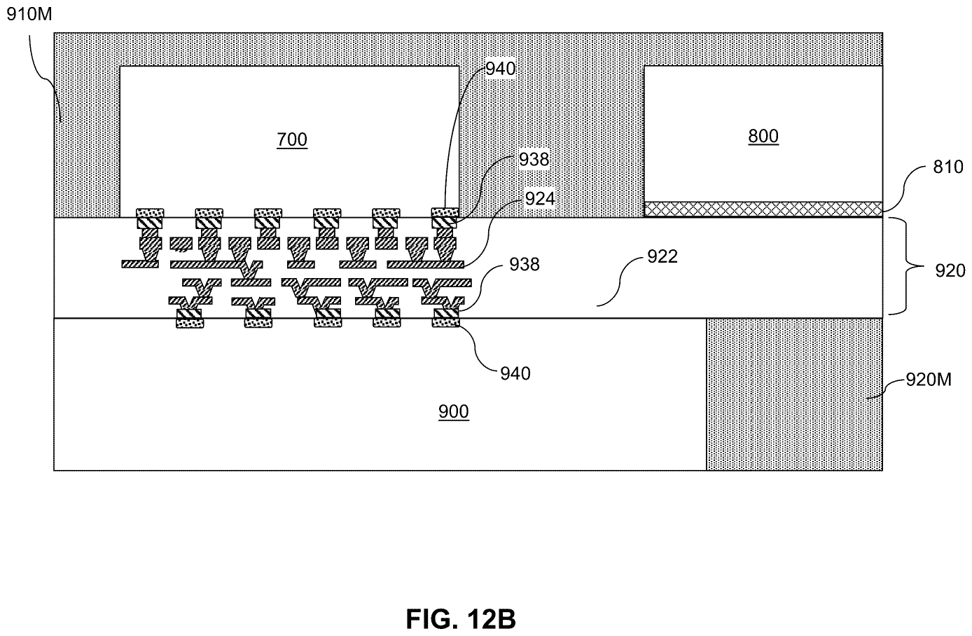

Referring to FIGS. 12A and 12B, illustrates an example of a chip stacking design with an additional semiconductor die 900, also referred to as an additional functional die 900, may be attached to the interposer 920. In some embodiments, the additional semiconductor die 900 is attached to the interposer 920 by interposer bonding pads 938 and die bonding pads 940 in the same manner as semiconductor die 700 described above.

As shown in FIG. 12A, a side (right) of the semiconductor die 900 is co-planar with a side (right) of the dummy die 800. This stacking design may be advantageous when forming small semiconductor packages.

As shown in FIG. 12B, a side (right) of the dummy die 800 extends beyond a side (right) of the additional semiconductor die 900. An additional molding compound 920M may be formed to be co-planar with the dummy die 800. The additional molding compound 920M acts as a buffer area to prevent die cracking. This stacking design may be advantageous when forming larger semiconductor packages.

The following discussion now refers to a number of methods and operations. Although the method operations are discussed in specific orders or are illustrated in a flow chart as being performed in a particular order, no order is required unless expressly stated or required because an operation is dependent on another operation being completed prior to the operation being performed.

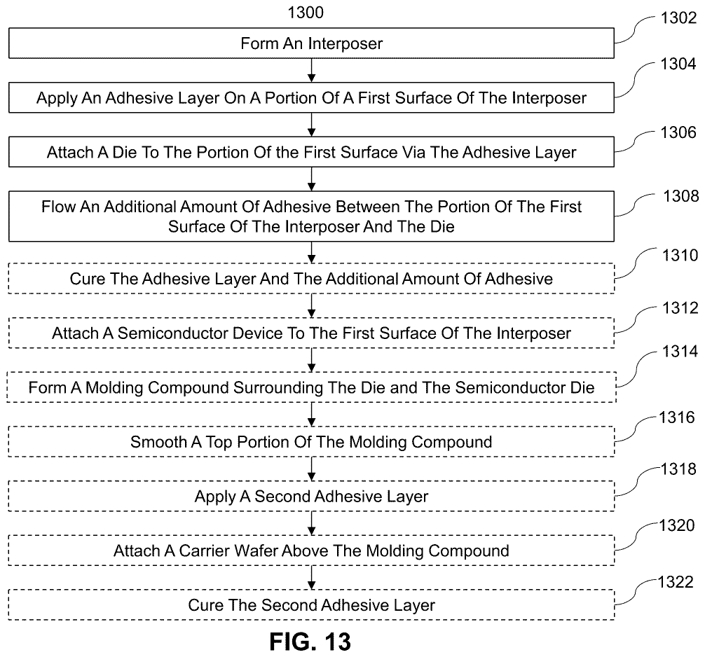

Embodiments are now described with reference to FIG. 13, which is a flow diagram of an example method 1300 for forming a semiconductor device by attaching components using an adhesive bonding structure. Operation 1302 may include forming an interposer 920. Referring to FIGS. 1A, 2A, and 2B, in operation 1302, an interposer 920 is formed that includes a dielectric layer 922 and interconnect wirings 924. Additionally, the interposer may include interposer bonding pads 938. The interposer 920 may be formed above a substrate 300 attached to the interposer by an adhesive layer 301.

Operation 1304 may include applying an adhesive layer 810 on a portion of a first surface of the interposer 920. Referring to FIGS. 1A and 3A-3C, in operation 1304, an adhesive layer 810 may be applied to a portion of a top surface of the interposer 920 where a die will be attached. The adhesive layer 810 may be formed of a material with a high thermal conductivity material (e.g., greater than 1 W/m*K) such as polyimide, a molding compound, a light resistance material, or other appropriate materials. In some embodiments, the adhesive material 810 may be patterned (FIGS. 4A and 4B) to increase surface area of the adhesive material 810 to provide enhanced adhesion. The adhesive material 810 may be patterned as a line pattern, lattice, honeycomb, spherical, or other appropriate patterns.

Operation 1306 may include attaching a die 800 to the portion of the first surface of the interposer 920 via the adhesive layer 810. Referring to FIGS. 1A and 3A-3C, in operation 1306, the die 800 may be attached to the interposer 920 via the adhesive layer 810. In some embodiments, the die 800 may be a dummy die or a die without circuits. The adhesive material 810 may provide a bonding interface between the die 800 and the interposer 920.

Operation 1308 may include flowing an additional amount of adhesive 810 between the portion of the first surface of the interposer 920 and the die 800 to fill in a gap between the first surface of the interposer 920 and the die 800. Referring to FIGS. 1A and 3A-3C, in operation 1308, an additional amount of adhesive 810 may be flowed between the interposer 920 and the die 800 to fill in any gaps. For example, the adhesive material 810 may be a flowable material that fills in any gaps caused by particle induced non-bonding (FIG. 3B) and/or thickness induced non-bonding (FIG. 3C). Thereby the adhesive material 810 may be a fluid material that fills in any gaps. As a result, the bonding interface between the die 800 and the interposer 920 may be substantially free from gaps and resulting in a proper and adequate bonding interface.

Optional operation 1310 may include curing the adhesive layer 810 and the additional amount of adhesive 810 to form a cured adhesive 810. Referring to FIG. 1A and 3A-3C, in operation 1310, the applied adhesive 810 may be cured to form a cured adhesive 810 with a thickness of between about 0.1 μm to about 10 mm. In some embodiments, the thickness may be about 20 μm to balance adhesion strength and mechanical stress between the die 800 and the interposer 920. The adhesive 810 may be cured by heating, UV irradiation, or other appropriate methods. In particular, UV irradiation may be used in areas not easily accessible while heating may be used in areas easily accessible. The cured adhesive 810 may provide a hardened and proper bonding interface substantially free of gaps caused by either particle induced non-bonding or thickness induced non-bonding. The cured adhesive 810 may be a solidified material ensuring adequate bonding between the interposer 920 and die 800.

Optional operation 1312 may include attaching a semiconductor die 700 to the first surface of the interposer 920. Referring to FIGS. 1A and 3A-3C, in optional operation 1312, a semiconductor die 700 may be attached to the interposer 920. The semiconductor die 700 may be a functional die such as a HBM, SoC, or other semiconductor die. The semiconductor die 700 may be placed about 0.1 μm to about 300 mm, or about 50 μm away from the die 800 based on the sizes of the dies and to avoid empty space within the semiconductor device. In some embodiments the semiconductor die 700 is attached to the interposer 920 by a metal-to-metal and/or dielectric-to-dielectric bond between the interposer bonding pads 928 and die bonding pads 940 as well as between the dielectric layer 922 and dielectric material within the semiconductor die 700.

Optional operation 1314 may include forming a molding compound 920M surrounding the die 800. Referring to FIGS. 5A-5C, in operation 1314, a molding compound 920M may be formed surrounding the die 800. The molding compound 920M may surround the die 800 and the semiconductor die 700. By encapsulating the semiconductor die 700 and the die 800, the molding compound 920M may protect the dies from environmental factors, provide mechanical strength, provide a stress balance to the edge of the adhesive material 810, and to fill in any gaps within the device. In some embodiments, the semiconductor die 700 and the die 800 may have varying heights and therefore the molding compound 910M provides a flat top surface to the overall device.

Optional operation 1316 may include smoothing a top surface of the molding compound 920M. Referring to FIGS. 6A and 6B, in operation 1316, a top surface of the molding compound 920M may be smoothed to form a substantially flat top surface. The substantially top surface allows additional components to be added above the molding compound 920M, regardless of the height or surface of the semiconductor die 700 and the die 800. The top surface of the molding compound 920M may be smoothed by a chemical mechanical polishing method, drilling, sanding, or other appropriate smoothing methods.

Optional operation 1318 may include applying a second adhesive layer 410 on the top surface of the molding compound 910M. Referring to FIG. 9, in operation 1318, a second adhesive layer 410 is applied to the top of the molding compound 910M. The second adhesive layer 410 may be formed of a material with a high thermal coefficient (e.g., greater than 1 W/m*K) similarly to the adhesive layer 810. The adhesive layer 810 may be formed of polyimide, molding material, light reactive material, or other appropriate flowable materials. Further, the adhesive layer 810 may be applied on only certain sections of the top surface of the molding compound 910M and the dies (e.g., semiconductor die 700 and die 800) or on the entire surface. The adhesive layer 810 may also be patterned similarly to adhesive layer 810 (FIG. 4A) to increase surface area of the adhesive layer 810. In some embodiments, only a portion of the adhesive layer 810 may be patterned based on the desired surface area of the adhesive layer 810.

Optional operation 1320 may include attaching a carrier wafer 400 above the molding compound 910M. Referring to FIG. 9, in operation 1320, a carrier wafer 400 is attached to the molding compound 910M via the second adhesive layer 410. The carrier wafer 400 may be a glass wafer formed of silicon dioxide, aluminum oxide, or other appropriate glass materials. In an alternative embodiment, the carrier wafer 400 may be a heat dissipation cover formed of a metal to improve heat management and reduce die temperature during operation.

Optional operation 1322 may include curing the second adhesive layer 410 to form a cured adhesive. Referring to FIG. 9, in operation 1322, the second adhesive layer 410 may be cured to form the cured adhesive. The second adhesive 410 may be cured with heating in accessible areas and UV irradiation in inaccessible areas. The thickness of the cured second adhesive 410 may be between about 0.1 μm and about 10 mm, or about 20 μm. The thickness of the cured second adhesive 410 may be adjusted to provide proper adhesion while balancing mechanical stress between the bonded areas. The cured adhesive layer 410 may be a solidified material that provides an adequate bonding interface between the molding compound 910M, semiconductor die 700 and die 800 and the carrier wafer 400 substantially free of gaps caused by either particle induced non-bonding or thickness induced non-bonding.

Referring to all drawings and according to various embodiments, a semiconductor device may include an interposer 920 and a die 800 having a bottom surface bonded to a top surface of the interposer 920 using an adhesive material 810, in which the adhesive material 810 substantially fills a gap between the top surface of the interposer 920 and the die 800.

In some embodiments, the semiconductor device further includes a molding compound 910M surrounding the die 800. In some embodiments, the adhesive material 810 is patterned. In some embodiments, the adhesive material 810 surrounds a particle defect 820 located on the top surface of the interposer 920. In some embodiments, the adhesive 810 fills in a side gap 830 between the interposer 920 and the die 800.

In an alternative embodiment, a semiconductor device includes an interposer 920, a semiconductor die 700 attached to a top surface of the interposer 920, a dummy die 800 attached to the top surface of the interposer 920, an adhesive layer 810 located between the top surface of the interposer 920 and a bottom surface of the dummy die 800, and a molding compound 910M surrounding the semiconductor die 700 and the dummy die 800.

In some embodiments, the semiconductor die 700 having a first height and the dummy die 800 having a second height that is different from the first height. In some embodiments, the molding compound 910M has a substantially flat top surface. In some embodiments, the semiconductor device further includes a carrier wafer 400, and a second adhesive layer 410 located between the carrier wafer 400 and the molding compound 910M. In some embodiments, the semiconductor device further includes a substrate 1120 attached to a bottom surface of the interposer 920, and a plurality of vias 1124 located through the substrate 1120. In some embodiments, the semiconductor device further includes a second semiconductor die 700′ attached to the top surface of the interposer 920, in which the dummy die 800 is located between the semiconductor die 700 and the second semiconductor die 700′. In some embodiments, the semiconductor structure further includes a second dummy die 800′ attached to the top surface of the interposer 920, in which the semiconductor die 700 is located between the dummy die 800 and the second dummy die 800′. In some embodiments, the semiconductor device further includes a second semiconductor die 900 attached to a second side of the interposer 920. In some embodiments, a side of the dummy die 800 is substantially coplanar with a side of the second semiconductor die 900. In some embodiments, the semiconductor device further includes a second molding compound 920M located on the second side of the interposer 920, in which the second molding compound 920M is located on a side of the second semiconductor die 900 and a side of the dummy die 800 is substantially coplanar with a side of the second molding compound 920M. The second molding compound 920M may allow the dummy die 800 to be closer to the stacking edge of the semiconductor device than the additional semiconductor die 900.

In an alternative embodiment, a method for forming a semiconductor device includes forming an interposer 920, applying an adhesive layer 810 on a portion of a first surface of the interposer 920 attaching a die 800 to the portion of the top surface of the interposer 920 via the adhesive layer 810, and flowing an additional amount of adhesive 810 between the portion of the top surface of the interposer 920 and the die 800 to fill in a gap 830 between the top surface of the interposer 920 and the die 800.

In some embodiments, the method further includes curing the adhesive layer 810 and the additional amount of adhesive 810 to form a cured adhesive 810, wherein the cured adhesive 810 has a thickness of between about 0.1 μm to about 10 mm. In some embodiments, the method further includes forming a molding compound 910M surrounding the die 800. In some embodiments, the method further includes smoothing a top portion of the molding compound 910M, applying a second adhesive layer 410 on the top portion of the molding layer 910M, and attaching a carrier wafer 400 above the molding compound 910M, in which the second adhesive layer 410 is located between the molding compound 910M and the carrier wafer 400. In some embodiments, the method further includes a semiconductor die 700 attached to the first surface of the interposer 920, and a molding compound 910M surrounding the semiconductor die 700 and the die 800, in which a top surface of the molding compound 910M is substantially planar.

Various embodiments relate to an adhesive bonding structure as an alternative to fusion bonding within a semiconductor device. Various embodiments address the challenge of bonding interface non-bonding defects due to surface abnormalities thereby reducing bonding defects and improving device yield. For example, if a particle or defect is located on a surface of a first layer, a fusion bond interface may fail to adequately connect the first layer to a second layer due to a gap surrounding the particle. Further, a gap between layers may cause a thickness induced non-bond between the layers that includes a gap on the sides of the bonding interface. In both instances of a particle induced non-bond and a thickness induced non-bond, a fusion bond may not adequately bond layers due to gaps thereby causing the device to fail and even be discarded. By using an adhesive bonding structure, gaps caused by either particles or differing thicknesses may be filled creating an adequate bonding interface between layers. Various embodiments may thereby utilize a flowable adhesive material to improve bonding between non-circuit layers. Various embodiments may fill large non-bonded areas caused by particles and adjust thickness non-bonding due to die warpage. As a result, various embodiments reduce costs and replace traditional fusion bonding interface dielectric films with an adhesive bonding structure. Additionally, the adhesive bonding structure may be formed of materials that may increase thermal conductivity of the overall device. Overall, various embodiments may reduce bonding defects thereby improving device yield due to proper bonding between layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the scope of the present disclosure, and that they may make various changes, substitutions, and alterations herein without departing from the scope of the claims.

What is claimed is:

1. A semiconductor device, comprising:
an interposer having a top surface;
an adhesive material; and
a die having a bottom surface bonded to the top surface of the interposer via the adhesive material, wherein the adhesive material substantially fills any gap between the top surface of the interposer and the bottom surface of the die.

2. The semiconductor device of claim 1, further comprising a molding compound surrounding the die.

3. The semiconductor device of claim 1, wherein the adhesive material is patterned.

4. The semiconductor device of claim 1, wherein the adhesive material surrounds a particle defect located on the top surface of the interposer.

5. The semiconductor device of claim 1, wherein the adhesive fills in a side gap between the interposer and the die.

6. A semiconductor device, comprising:
an interposer;
a semiconductor die attached to a top surface of the interposer;
a dummy die attached to the top surface of the interposer;
an adhesive layer located between the top surface of the interposer and a bottom surface of the dummy die; and
a molding compound surrounding the semiconductor die and the dummy die.

7. The semiconductor device of claim 6, wherein the semiconductor die having a first height and the dummy die having a second height that is different from the first height.

8. The semiconductor device of claim 6, wherein the molding compound has a substantially flat top surface.

9. The semiconductor device of claim 6, further comprising:
a carrier wafer; and
a second adhesive layer located between the carrier wafer and the molding compound.

10. The semiconductor device of claim 6, further comprising:
a substrate attached to a bottom surface of the interposer; and
a plurality of vias located through the substrate.

11. The semiconductor device of claim 6, further comprising a second semiconductor die attached to the top surface of the interposer, wherein the dummy die is located between the semiconductor die and the second semiconductor die.

12. The semiconductor device of claim 6, further comprising a second dummy die attached to the top surface of the interposer, wherein the semiconductor die is located between the dummy die and the second dummy die.

13. The semiconductor device of claim 6, further comprising a second semiconductor die attached to the bottom surface of the interposer.

14. The semiconductor device of claim 13, wherein a side of the dummy die is substantially coplanar with a side of the second semiconductor die.

15. The semiconductor device of claim 13, further comprising a second molding compound located on the second side of the interposer, wherein the second molding compound is located on a side of the second semiconductor die and a side of the dummy die is substantially coplanar with a side of the second molding compound.

16. A method for forming a semiconductor device, the method comprising:
forming an interposer;
applying an adhesive layer on a portion of a top surface of the interposer;
attaching a die to the portion of the top surface of the interposer via the adhesive layer; and
flowing an additional amount of adhesive between the portion of the top surface of the interposer and the die to fill in a gap between the top surface of the interposer and the die.

17. The method of claim 16, further comprising curing the adhesive layer and the additional amount of adhesive to form a cured adhesive, wherein the cured adhesive has a thickness of between about 0.1 μm to about 10 mm.

18. The method of claim 16, further comprising forming a molding compound surrounding the die.

19. The method of claim 18, further comprising:
smoothing a top surface of the molding compound;
applying a second adhesive layer on the top surface of the molding layer;
attaching a carrier wafer above the molding compound, wherein the second adhesive layer is located between the molding compound and the carrier wafer; and
curing the second adhesive layer to form a cured adhesive, wherein the cured adhesive has a thickness of between about 0.1μm to about 10 mm.

20. The method of claim 16, further comprising:
attaching a semiconductor die to the top surface of the interposer; and
forming a molding compound surrounding the semiconductor die and the die,
wherein a top surface of the molding compound is substantially planar.
